(19) United States
(12) Patent Application Publication
(10) Pub. No.: US 2025/0138092 A1
(43) Pub. Date: May 1, 2025

(54) MULTI-STAGE FILTER FOR BATTERY HEALTH PARAMETER

(71) Applicant: Medtronic, Inc., Minneapolis, MN (US)

(72) Inventor: Gang Ji, Medina, MN (US)

(21) Appl. No.: 18/925,415

(22) Filed: Oct. 24, 2024

Related U.S. Application Data
(60) Provisional application No. 63/546,017, filed on Oct. 27, 2023.

(51) Int. Cl. G01R 31/36; G01R 31/378; G01R 31/382; G01R 31/389; G01R 31/392

(52) U.S. Cl. CPC G01R 31/3648; G01R 31/378; G01R 31/382; G01R 31/389; G01R 31/392

(57) ABSTRACT

The present disclosure provides a battery health management device including at least one sensor coupled to a battery, and a controller coupled to the at least one sensor and including a processor coupled to a memory comprising instructions, the processor configured to execute the instructions to receive a plurality of battery health input values associated with a battery health parameter over a predetermined period of time, determine an updated battery health value based on the plurality of battery health input values, determine that each battery health input value included in the plurality of battery health input values meets a predetermined trend condition, calculate a difference value, determine that the difference value is less than or equal to a predetermined upper bound battery health value and greater than or equal to a predetermined lower bound battery health value, and update the reference battery health value.

### RELATED APPLICATIONS

This application claims the benefit of U.S. Provisional Application Ser. No. 63/546,017, filed Oct. 27, 2023, the entire contents of each of which are incorporated herein by reference.

### BACKGROUND

Batteries are known to be used in certain medical devices such as portable imaging devices. In such devices, it is desirable that the battery's health be monitored.

### SUMMARY

The techniques of this disclosure generally relate to methods, systems, and apparatuses for updating one or more health parameter values associated with a battery.

In one aspect, the present disclosure provides a battery health management device including at least one sensor coupled to a battery, and a controller coupled to the at least one sensor and comprising a processor coupled to a memory including instructions, the processor configured to execute the instructions to receive, using the at least one sensor, a plurality of battery health input values associated with a battery health parameter over a predetermined period of time, determine an updated battery health value based on the plurality of battery health input values, determine that each battery health input value included in the plurality of battery health input values meets a predetermined trend condition, calculate a difference value based on the updated battery health value and a reference battery health value associated with the battery, determine that the difference value is less than or equal to a predetermined upper bound battery health value and greater than or equal to a predetermined lower bound battery health value, and update the reference battery health value to be equal to the updated battery health value

In another aspect, the present disclosure provides a health management method for a battery including receiving, using at least one sensor coupled to the battery, a plurality of battery health input values associated with a battery health parameter over a predetermined period of time, determining an updated battery health value based on the plurality of battery health input values, determining that each battery health input value included in the plurality of battery health input values meets a predetermined trend condition, calculating a difference value based on the updated battery health value and a reference battery health value associated with the battery, determining that the difference value is less than or equal to a predetermined upper bound battery health value and greater than or equal to a predetermined lower bound battery health value, and updating the reference battery health value to be equal to the updated battery health value.

In yet another aspect, the present disclosure provides non-transitory computer readable medium storing computer program instructions for health management of a battery, the computer program instructions when executed by a processor cause the processor to perform operations including receiving, using at least one sensor coupled to the battery, a plurality of battery health input values associated with a battery health parameter over a predetermined period of time, determining an updated battery health value based on the plurality of battery health input values, determining that each battery health input value included in the plurality of battery health input values meets a predetermined trend condition, calculating a difference value based on the updated battery health value and a reference battery health value associated with the battery, determining that the difference value is less than or equal to a predetermined upper bound battery health value and greater than or equal to a predetermined lower bound battery health value, and updating the reference battery health value to be equal to the updated battery health value.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF DRAWINGS

FIG. 1 illustrates an exemplary block diagram of a battery powered medical system;

FIG. 2 illustrates an exemplary block diagram of components of a system;

FIG. 3A illustrates an exemplary flow diagram of a process for updating a battery health value using a multistage filtering technique;

FIG. 3B illustrates an exemplary flow diagram of another process for updating a battery health value using a multistage filtering technique;

FIG. 4 illustrates an exemplary battery capacity value updating graph;

FIG. 5 illustrates an exemplary battery resistance value updating graph;

FIG. 6A illustrates a battery capacity value trend line graph without using a multistage filtering technique;

FIG. 6B illustrates a battery capacity fade rate value trend line graph without using a multistage filtering technique;

FIG. 6C illustrates an elective replacement indicator value and end of service indicator value trend line graph without using a multistage filtering technique;

FIG. 7A illustrates a battery capacity value trend line graph using a multistage filtering technique;

FIG. 7B illustrates a battery capacity fade rate value trend line graph using a multistage filtering technique;

FIG. 7C illustrates an elective replacement indicator value and end of service indicator value trend line graph using a multistage filtering technique;

FIG. 8 illustrates an exemplary imaging system in accordance with some embodiments; and

FIG. 9 illustrates an exemplary process for filtering battery capacity values.

### DETAILED DESCRIPTION

Battery capacity corresponds to the quantity of electric charge that can be accumulated during battery charging, stored in open circuit conditions, and released during battery discharge. When the battery is discharged with constant current, battery capacity is given by the formula C_{d}=I·t_{d}, where t_{d} is the discharge duration and I is current. When discharge duration is expressed in hours, the typical unit for battery capacity is the Ampere-hour (AH).

Battery resistance is another important parameter for tracking battery health. Batteries with large internal resistance may not be able to supply current as well as batteries with lower internal resistance due to the increased voltage drop. The voltage at the terminals of that battery indicates State of charge (SoC) of a battery when the battery is at rest, or in equilibrium. The mathematical relationship between SoC and equilibrium voltage is a known relationship and is based on battery type. Equilibrium voltage and SoC can be used to determine total capacity and remaining capacity of the battery.

However, as the battery ages, the total capacity of the battery fades while battery resistance increases. Without adequately tracking the total capacity of battery, the estimate of the SoC and remaining capacity of the battery will become less accurate. Additionally, without accurately tracking total battery capacity and/or battery resistance, it can be difficult to determine when the battery needs to be replaced. These and other issues can lead to safety implications in a clinical environment, for example, where it is important to know total remaining capacity of batteries and/or that the batteries can adequately supply power to medical devices such as portable imaging systems.

Certain sensors used to sense various parameters of a battery such as voltage, current, resistance, and other parameters relevant to the calculation of battery capacity values and/or battery resistance values may provide unreliable measurement values to a battery management system. When unreliable battery capacity values and/or battery resistance values are used, battery capacity change rate values and/or battery resistance change rate values may be miscalculated, further resulting in miscalculation of elective replacement indicator values and/or end of service indicator values.

To remedy these and other problems, embodiments provide systems and/or methods for multi-stage filtering of unusable and/or unreliable battery capacity values and/or battery resistance values. Some embodiments provide a battery management system configured to perform multi-stage filtering on battery capacity values associated with a battery included in a mobile imaging device, for example.

Embodiments of the disclosure are defined in the claims. However, below there is provided a non-exhaustive listing of non-limiting examples. Any one or more of the features of these examples may be combined with any one or more features of another example, embodiment, or aspect described herein.

Example Ex1. A battery health management device comprises at least one sensor coupled to a battery, and a controller coupled to the at least one sensor and comprising a processor coupled to a memory comprising instructions, the processor configured to execute the instructions to receive, using the at least one sensor, a plurality of battery health input values associated with a battery health parameter over a predetermined period of time, determine an updated battery health value based on the plurality of battery health input values, determine that each battery health input value included in the plurality of battery health input values meets a predetermined trend condition, calculate a difference value based on the updated battery health value and a reference battery health value associated with the battery, determine that the difference value is less than or equal to a predetermined upper bound battery health value and greater than or equal to a predetermined lower bound battery health value, and update the reference battery health value to be equal to the updated battery health value.

Example Ex2. The battery health management device of Example Ex1, wherein the processor is further configured execute the instructions to generate a notification based on the updated reference battery health value, cause the notification to be displayed at a user interface.

Example Ex3. The battery health management device of Examples Ex1-Ex2, wherein the determining that each battery health input value included in the plurality of battery health input values meets the predetermined trend condition comprises determining that each battery health input value included in the plurality of battery health input values is less than the reference battery health value.

Example Ex4. The battery health management device of Examples Ex1-Ex3, wherein the determining that each battery health input value included in the plurality of battery health input values meets the predetermined trend condition comprises determining that each battery health input value included in the plurality of battery health input values is greater than the reference battery health value.

Example Ex5. The battery health management device of Examples Ex1-Ex1, wherein the battery health parameter is one of battery resistance or battery capacity.

Example Ex6. The battery health management device of Examples Ex1-Ex5, wherein each of the plurality of battery health input values are taken at different times within the predetermined time period.

Example Ex7. The battery health management device of Examples Ex1-Ex6, wherein the determining the updated battery health value based on the plurality of battery health input values comprises calculating a mean, median, or modal battery health input value based on the plurality of battery health input values, and setting the updated battery health value to be equal to the mean, median, or modal battery health input value.

Example Ex8. The battery health management device of Examples Ex1-Ex7, wherein the reference battery health value is associated with a first time value, and the predetermined upper bound battery health value is determined based on the reference battery health value and a second reference battery health value associated with a second time value preceding the first time value.

Example Ex9. The battery health management device of Example Ex8, wherein the processor is further configured execute the instructions to calculate the predetermined upper bound battery health value based on the difference between the second reference battery health value and the reference battery health value.

Example Ex10. The battery health management device of Examples Ex1 Ex9, wherein the reference battery health value is associated with a first time value, and the predetermined lower bound battery health value is determined based on the reference battery health value and a second reference battery health value associated with a second time value preceding the first time value.

Example Ex11. The battery health management device of Example Ex10, wherein the processor is further configured execute the instructions to calculate the predetermined lower in bound battery health value based on the difference between the reference battery health value and the second reference battery health value.

Example Ex12. The battery health management device of Examples Ex1-Ex11, wherein the processor is further configured to execute the instructions to determine each battery health input value is not equal to the reference battery value.

Example Ex13. The battery health management device of Examples Ex1-Ex12, wherein the at least one sensor comprises at least one of a current sensor, a voltage sensor, a resistance sensor, a temperature sensor, or a pressure sensor.

Example Ex14. The battery health management device of Examples Ex1-Ex13, wherein the battery health management device includes the battery, and wherein the battery comprises a lithium ion battery.

Example Ex15. The battery health management device of Examples Ex1-Ex14, wherein the battery is included in a medical imaging device.

Example Ex16. A health management method for a battery comprises receiving, using at least one sensor coupled to the battery, a plurality of battery health input values associated with a battery health parameter over a predetermined period of time, determining an updated battery health value based on the plurality of battery health input values, determining that each battery health input value included in the plurality of battery health input values meets a predetermined trend condition, calculating a difference value based on the updated battery health value and a reference battery health value associated with the battery, determining that the difference value is less than or equal to a predetermined upper bound battery health value and greater than or equal to a predetermined lower bound battery health value, and updating the reference battery health value to be equal to the updated battery health value.

Example Ex17. The method of Example Ex16 further comprising generating a notification based on the updated reference battery health value, and causing the notification to be displayed at a user interface.

Example Ex18. The method of Examples Ex16-Ex17, wherein the determining that each battery health input value included in the plurality of battery health input values meets the predetermined trend condition comprises determining that each battery health input value included in the plurality of battery health input values is less than the reference battery health value.

Example Ex19. The method of Examples Ex16-Ex18, wherein the determining that each battery health input value included in the plurality of battery health input values meets the predetermined trend condition comprises determining that each battery health input value included in the plurality of battery health input values is greater than the reference battery health value.

Example Ex20. The method of Examples Ex16-Ex19, wherein the battery health parameter is one of battery resistance or battery capacity.

Example Ex21. The method of Examples Ex16-Ex20, wherein each of the plurality of battery health input values are taken at different times within the predetermined time period.

Example Ex22. The method of Examples Ex16-Ex21, wherein the determining the updated battery health value based on the plurality of battery health input values comprises calculating a mean, median, or modal battery health input value based on the plurality of battery health input values, and setting the updated battery health value to be equal to the mean, median, or modal battery health input value.

Example Ex23. The method of Examples Ex16-Ex22, wherein the reference battery health value is associated with a first time value, and the predetermined upper bound battery health value is determined based on the reference battery health value and a second reference battery health value associated with a second time value preceding the first time value.

Example Ex24. The method of Example Ex23 further comprising calculating the predetermined upper bound battery health value based on the difference between the second reference battery health value and the reference battery health value.

Example Ex25. The method of Examples Ex16-Ex24, wherein the reference battery health value is associated with a first time value, and the predetermined lower bound battery health value is determined based on the reference battery health value and a second reference battery health value associated with a second time value preceding the first time value.

Example Ex26. The method of Example Ex25 further comprising calculating the predetermined lower bound battery health value based on the difference between the reference battery health value and the second reference battery health value.

Example Ex27. The method of Examples Ex16-Ex26 further comprising determining each battery health input value is not equal to the reference battery value.

Example Ex28. The method of Example Ex16-Ex27, wherein the at least one sensor comprises at least one of a current sensor, a voltage sensor, a resistance sensor, a temperature sensor, or a pressure sensor.

Example Ex29. The method of Examples Ex16-Ex28, wherein the battery comprises a lithium ion battery.

Example Ex30. The method of Examples Ex16-Ex29, wherein the battery is included in a medical imaging device.

Example Ex31. A non-transitory computer readable medium storing computer program instructions for health management of a battery, the computer program instructions when executed by a processor cause the processor to perform operations comprising receiving, using at least one sensor coupled to the battery, a plurality of battery health input values associated with a battery health parameter over a predetermined period of time, determining an updated battery health value based on the plurality of battery health input values, determining that each battery health input value included in the plurality of battery health input values meets a predetermined trend condition, calculating a difference value based on the updated battery health value and a reference battery health value associated with the battery, determining that the difference value is less than or equal to a predetermined upper bound battery health value and greater than or equal to a predetermined lower bound battery health value, and updating the reference battery health value to be equal to the updated battery health value.

Example Ex32. The non-transitory computer readable medium of Example Ex31, wherein the computer program instructions when executed by the processor further cause the processor to perform operations comprising generating a notification based on the updated reference battery health value, and causing the notification to be displayed at a user interface.

Example Ex33. The non-transitory computer readable medium of Examples Ex31-Ex32, wherein the determining that each battery health input value included in the plurality of battery health input values meets the predetermined trend condition comprises determining that each battery health input value included in the plurality of battery health input values is less than the reference battery health value.

Example Ex34. The non-transitory computer readable medium of Examples Ex31-Ex33, wherein the determining that each battery health input value included in the plurality of battery health input values meets the predetermined trend condition comprises determining that each battery health input value included in the plurality of battery health input values is greater than the reference battery health value.

Example Ex35. The non-transitory computer readable medium of Examples Ex31-Ex34, wherein the battery health parameter is one of battery resistance or battery capacity.

Example Ex36. The non-transitory computer readable medium of Examples Ex31-Ex35, wherein each of the plurality of battery health input values are taken at different times within the predetermined time period.

Example Ex37. The non-transitory computer readable medium of Examples Ex31-Ex36, wherein the determining the updated battery health value based on the plurality of battery health input values comprises calculating a mean, median, or modal battery health input value based on the plurality of battery health input values, and setting the updated battery health value to be equal to the mean, median, or modal battery health input value.

Example Ex38. The non-transitory computer readable medium of Examples Ex31-Ex37, wherein the reference battery health value is associated with a first time value, and the predetermined upper bound battery health value is determined based on the reference battery health value and a second reference battery health value associated with a second time value preceding the first time value.

Example Ex39. The non-transitory computer readable medium of Example Ex38, wherein the computer program instructions when executed by the processor further cause the processor to perform operations comprising calculating the predetermined upper bound battery health value based on the difference between the second reference battery health value and the reference battery health value.

Example Ex40. The non-transitory computer readable medium of Examples Ex31-Ex39, wherein the reference battery health value is associated with a first time value, and the predetermined lower bound battery health value is determined based on the reference battery health value and a second reference battery health value associated with a second time value preceding the first time value.

Example Ex41. The non-transitory computer readable medium of Example Ex40, wherein the computer program instructions when executed by the processor further cause the processor to perform operations comprising calculating the predetermined lower bound battery health value based on the difference between the reference battery health value and the second reference battery health value.

Example Ex42. The non-transitory computer readable medium of Examples Ex31-Ex41, wherein the computer program instructions when executed by the processor further cause the processor to perform operations comprising determining each battery health input value is not equal to the reference battery value.

Example Ex43. The non-transitory computer readable medium of Examples Ex31-Ex42, wherein the at least one sensor comprises at least one of a current sensor, a voltage sensor, a resistance sensor, a temperature sensor, or a pressure sensor.

Example Ex44. The non-transitory computer readable medium of Examples Ex31-Ex43, wherein the battery comprises a lithium ion battery.

Example Ex45. The non-transitory computer readable medium of Examples Ex31-Ex44, wherein the battery is included in a medical imaging device.

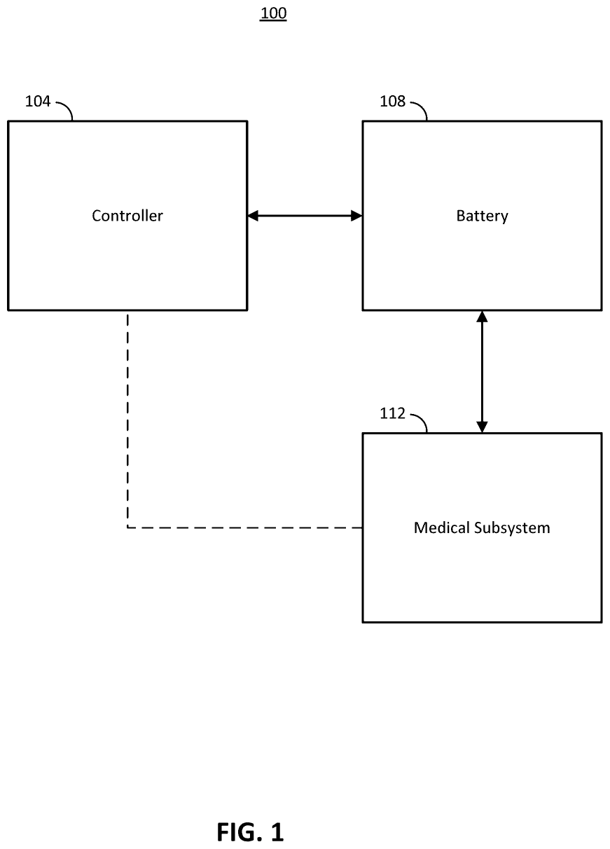

FIG. 1 illustrates an exemplary block diagram of a battery powered medical system 100. In some embodiments, the battery powered medical system 100 can include a controller 104, a battery 108, and a medical subsystem 112. The controller 104 can be coupled to the battery 108, and the battery 108 can be coupled to the medical subsystem 112. The controller 104 can be coupled to the battery 108 in order to receive power from the battery 108 and/or monitor operating conditions of the battery 108. For example, the controller 104 may be coupled to one or more sensors included in the battery 108 and/or a battery management system included in the battery 108.

In some embodiments, the battery 108 can supply power to the medical subsystem 112. In some embodiments, the medical subsystem 112 can include one or more components that use power from the battery 108 to perform one or more functions such as imaging and/or patient monitoring. In some embodiments, the medical subsystem 112 can be an imaging system. In some embodiments, the imaging system can be an x-ray imaging system (e.g., a 2D x-ray imaging system and/or a 3D x-ray imaging system). In some embodiments, the controller 104 can be coupled to the medical subsystem 112. In some embodiments, the controller 104 can cause the medical subsystem 112 to perform imaging. Thus, in some embodiments, the controller 104 may control and/or monitor the battery 108 and the medical subsystem 112.

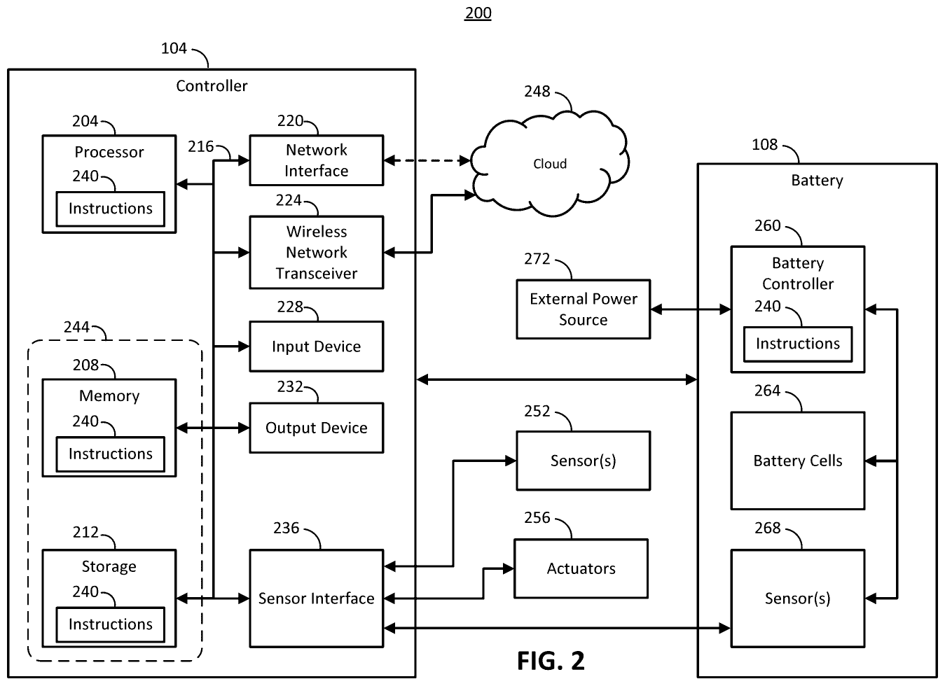

FIG. 2 illustrates an exemplary block diagram of components of a system 200. The battery management system 200 can include the controller 104 and the battery 108 in FIG. 2. In some embodiments, the controller 104 can include a processor 204, a memory 208, storage 212, an interconnect 216 (e.g., a bus), a network interface 220, a wireless network transceiver 224, an input device 228, an output device 232, and/or a sensor interface 236. In some embodiments, the controller 104 may include the processor 204, the memory 208, the sensor interface 236, and at least one of the network interface 220, the wireless network transceiver 224, and/or the output device 232. In some embodiments, the controller 104 may function as at least part of a battery management system.

Components included in the controller 104 may communicate over the interconnect 216. More specifically, the processor 204, the memory 208, the storage 212, the interconnect 216, the network interface 220, the wireless network transceiver 224, the input device 228, the output device 232, and/or the sensor interface 236 can be coupled together and communicate over the interconnect 216. The interconnect 216 may include any number of technologies, including industry standard architecture (ISA), extended ISA (EISA), peripheral component interconnect (PCI), peripheral component interconnect extended (PCIx), PCI express (PCIe), or any number of other technologies. The interconnect 216 may be a proprietary bus.

The controller 104 can include processing circuitry in the form of a processor 204, which may be a microprocessor, a multi-core processor, a multithreaded processor, an ultra-low voltage processor, an embedded processor, or other known processing elements. The processor 204 may be a part of a system on a chip in which the processor 204 and other components described herein are formed into a single integrated circuit.

The memory 208 may function as a system memory. Any number of memory devices may be used to provide for a given amount of system memory. As examples, the memory 208 may be random access memory (RAM). However, any other type of memory can be included. Persistent storage can also be provided by storage 212. Storage 212 may include disk drives, flash memory cards, Universal Serial Bus (USB) flash drives, etc.

The network interface 220 can be a network interface controller (NIC) that provides a wired communication to other devices or systems through the cloud 248. The wired communication may provide an Ethernet connection or may be based on other types of networks. The interconnect 216 may couple the processor 204 to the sensor interface 236. The sensor interface 236 can be used to connect additional devices or subsystems to the controller 104. These additional devices may include one or more sensors 252, which can include one or more voltage sensors, current sensors, resistance sensors, and/or other sensors used to sense battery health parameters of the battery 108. The sensor interface 236 further may be used to connect the controller 104 to actuators 256, such as power switches, valve actuators, an audible sound generator, a visual warning device, and the like.

The controller 104 may communicate wirelessly with other devices using the wireless transceiver 224. The wireless transceiver 224 may use any number of frequencies and protocols, IEEE, or Bluetooth protocols, although embodiments are not limited to these protocols. The wireless transceiver 224 may be included to communicate with devices or services in the cloud 248 via local or wide area network protocols.

The memory 208, the storage 212, and/or the processor 204 may include instructions 240 in the form of software, firmware, or hardware commands to implement the techniques described herein. Although such instructions 240 are shown as code blocks included in the memory 208 and the storage 212, it may be understood that any of the code blocks may be replaced with hardwired circuits, for example, built into an application specific integrated circuit (ASIC).

In some embodiments, various input/output (I/O) devices may be present within or connected to, the controller 104. For example, the output device 232 can be a display included to show information, such as sensor readings, battery capacity readings, battery health diagnostic outputs, battery health warnings, etc. The input device 228 can include a button, a touch screen and/or a keypad may be included to accept input. The output device 232 may include any number of forms of audio or visual display, including simple visual outputs such as binary status indicators (e.g., light-emitting diodes (LEDs)) and multi-character visual outputs, or more complex outputs such as display screens (e.g., liquid crystal display (LCD) screens), with the output of characters, graphics, multimedia objects, and the like being generated or produced from the operation of the controller 104. A display or console hardware, in the context of the present system, may be used to provide output and receive input of a medical device, including an implantable medical device; to identify a state of a medical device or related/connected devices; or to conduct any other number of management or administration functions.

In some embodiments, the battery 108 can provide power to the controller 104. In some embodiments, the controller 104 can include a battery (not shown) and/or be coupled to another power source (not shown), and monitor the battery 108 without receiving power from the battery 108.

The battery 108 can include a battery controller 260, one or more battery cells 264 (e.g., electrochemical cells), and/or one or more sensors 268. In some embodiments, the battery 108 can be a lithium ion battery such as a lithium cobalt oxide battery, a lithium iron phosphate battery, a lithium manganese oxide battery, a lithium nickel cobalt aluminum oxide battery, and/or a lithium nickel manganese cobalt oxide battery.

The battery controller 260 can be coupled to the one or more battery cells 264 and/or the one or more sensors 268. The one or more sensors 268 can include one or more voltage sensors, current sensors, resistance sensors, resistance estimators, capacity estimators, temperature sensors, pressure sensors, and/or other sensors used to sense battery health parameters of the battery cells 264. In some embodiments, each resistance estimator can include one or more sensors and be configured to generate a battery resistance estimation value based on data from the one or more sensors. In some embodiments, each capacity estimator can include one or more sensors and be configured to generate a battery capacity estimation value based on data from the one or more sensors. In some embodiments, the battery controller 260 and the one or more sensors 268 can form a battery management system. An external power source 272, or other power supply coupled to a grid, may be coupled with the battery controller 260 yet separate from the battery, to charge the battery 108. In other words, the external power source 272 can act as a charger in some embodiments. In some examples, the external power source 272 may be replaced with a wireless power receiver to obtain the power wirelessly.

In some embodiments, the battery controller 260 can include instructions 240 (e.g., in a memory, storage, and/or processor). In some embodiments, the battery controller can contain at least a portion of the components in the controller 104.

In some embodiments, the instructions 240 provided via the processor 204, the memory 208, the storage 212, and/or the battery controller 260 may be embodied as a non-transitory, machine-readable medium 244 including code to direct the processor 204 to perform electronic operations in the controller 104. The processor 204 may access the non-transitory, machine-readable medium 244 over the interconnect 216. For instance, the non-transitory, machine-readable medium 244 may be embodied by devices described for the storage 212 or may include specific storage units such as optical disks, flash drives, or any number of other hardware devices. The non-transitory, machine-readable medium 244 may include instructions to direct the processor 204 to perform a specific sequence or flow of actions, for example, as described with respect to the flowchart(s) and block diagram(s) of operations and functionality depicted below.

In some embodiments, a portion of the instructions 240 may be executed by the controller 104 (e.g., by the processor 204), and another portion of the instructions 240 can be executed by the battery controller 260. In some embodiments, the instructions 240 may be executed by only the controller 104. In other embodiments, the instructions 240 may be executed by only the battery controller 260. Thus, the controller 104 and/or the battery controller 260 can be used to implement a battery management system.

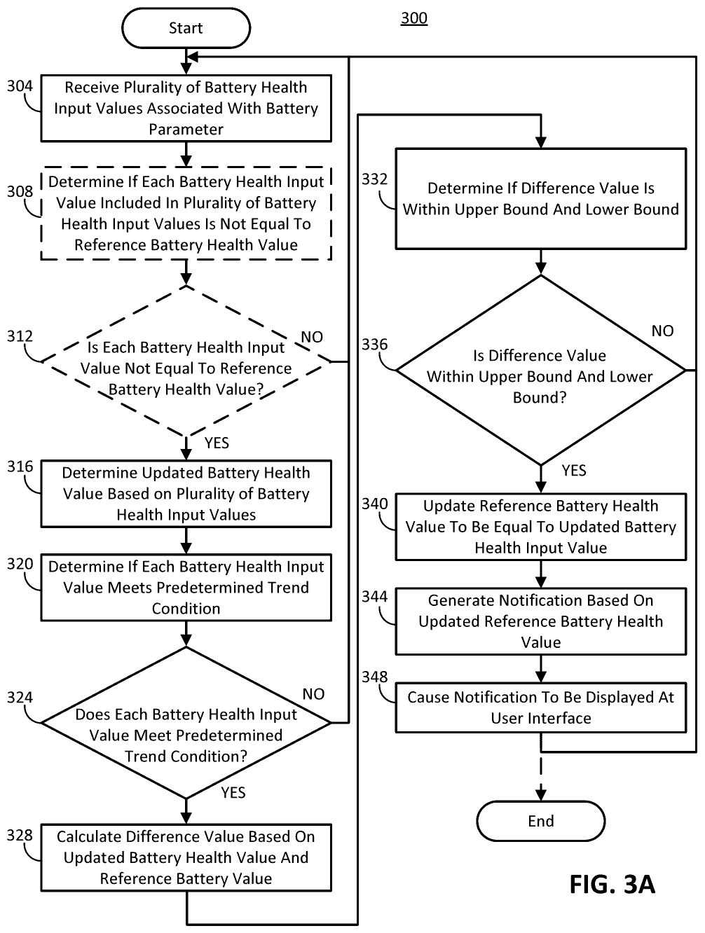

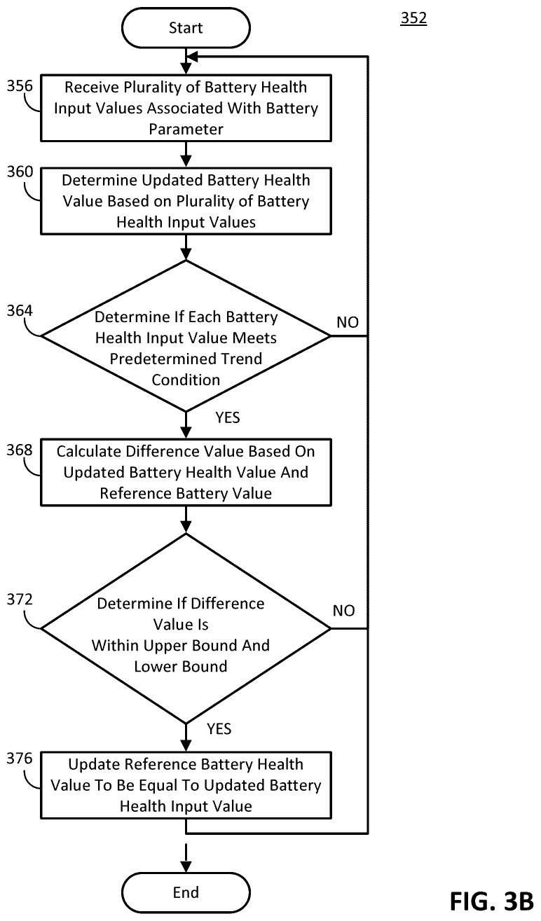

FIG. 3A illustrates an exemplary flow diagram of a process 300 for updating a battery health value using a multistage filtering technique. Referring to FIG. 3A as well as FIG. 1 and FIG. 2, in some embodiments, the process 300 can be implemented as instructions in the processor 204, the memory 208, the storage 212, and/or the battery controller 260 in (e.g., as instructions 240). In some embodiments, the process 300 can be executed by the controller 104 in (e.g., by the processor 204), and another portion of the process 300 can be executed by the battery controller 260. In some embodiments, the process 300 may be executed by only the controller 104. In other embodiments, the process 300 may be executed by only the battery controller 260. The process 300 can be used to monitor the health of the battery 108.

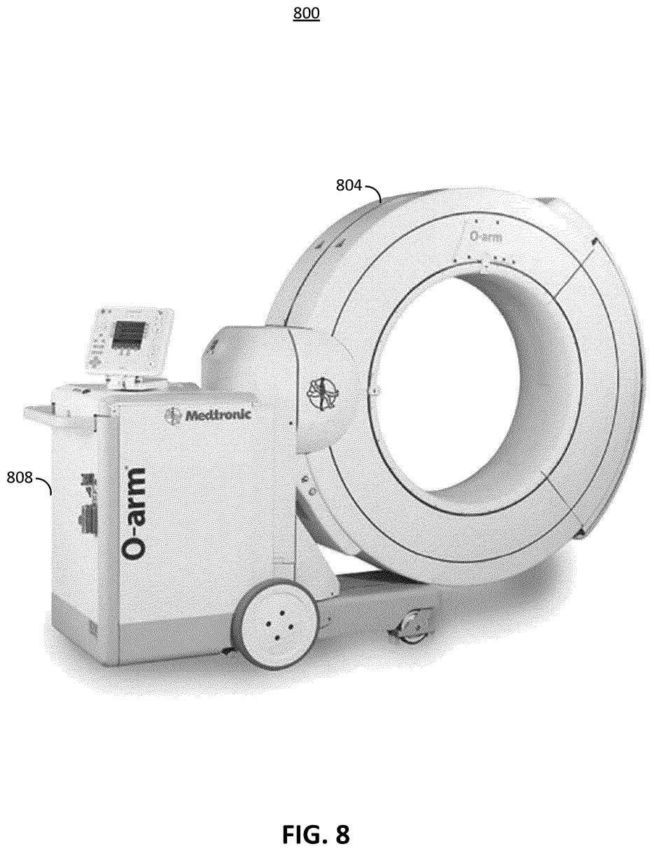

Referring now to FIG. 3A, at 304, the process 300 can receive a plurality of battery health input values associated with a battery health parameter. The process 300 can receive the plurality of battery health input values for a predetermined time period. The time period can be a predetermined length of time, such as about one hundred seconds. Each of the battery health input values included in the plurality of battery health input values can be associated with a discrete time point. Each time point can be evenly spaced apart for the duration of the time period. In some embodiments, each time point can be spaced about one second apart. In some embodiments, the process 300 can receive the plurality of battery health input values from one or more sensors. In some embodiments, the one or more sensors can include voltage sensors, current sensors, resistance sensors, and/or other sensors used to sense battery health parameters of a battery (e.g., the battery 108 in FIG. 8). In some embodiments, the process 300 can receive battery health input values that have been predetermined by an external process (e.g., by a process executed by a controller coupled to one or more sensors). In some embodiments, at 304, the process 300 can receive raw sensor data from one or more sensors and determine the plurality of battery health input values based on the raw sensor data.

In some embodiments, the battery health parameter can be battery capacity. In those examples, the plurality of battery health input values can include battery capacity values. The battery capacity values may be predetermined based on data from one or more sensors (e.g., voltage sensors and/or current sensors). In some embodiments, the battery health parameter can be battery resistance. In those embodiments, the plurality of battery health input values can include battery resistance values sensed by one or more resistance sensors.

At 308, the process 300 can determine if each battery health input value included in the plurality of battery health input values is not equal to a reference battery value associated with the battery. In some embodiments, the process 300 can determine if each battery health input value included in the plurality of battery health input values is not equal to a reference battery value associated with the battery for more than the time period. The reference battery value can be a predetermined value of the battery health parameter. For example, the reference battery value can be a battery capacity value and/or a battery resistance value associated with the battery. The reference battery value can be associated with a current health state of the battery (e.g., the current battery capacity and/or the current battery resistance). If each battery health input value is not equal to the reference battery value associated with the battery for more than the time period, the battery health input value may be checked against the trend condition. In some embodiments, 308 can be optional, and the process can proceed to 316 after 304.

At 312, if the process 300 has determined that at least one battery health input value included in the plurality of battery health input values is equal to the reference battery value (i.e., “NO” at 312), the process 300 can proceed to 304. At 312, if the process 300 has determined that each battery health input value included in the plurality of battery health input values is not equal to a reference battery value associated with the battery, the process 300 can proceed to 316. In some embodiments, 312 can be optional, and the process can proceed to 316 after 304.

At 316, the process 300 can determine an updated battery health value based on the plurality of battery health input values. In some embodiments. The process 300 can determine the updated battery health value by calculating a mean value based on the plurality of battery health input values and setting the updated battery health value to be equal to the mean value. In some embodiments the process 300 can determine the updated battery health value by determining a median or modal value of the plurality of battery health input values and setting the updated battery health value to be equal to said value such that the updated battery health value falls within the range of the plurality of battery health input values. In some embodiments the process 300 can determine the updated battery health value by determining a most recent battery health input value included the plurality of battery health input values (i.e., battery health input value associated with a most recent time point) and setting the updated battery health value to be equal to the most recent battery health input value.

At 320, the process 300 can determine if each battery health input value meets a predetermined trend condition. In some embodiments, the trend condition may specify that each battery health input value included in the plurality of battery health input values should be less than or greater than a predetermined threshold. In some embodiments, the predetermined threshold can be the reference battery health value. For certain battery health parameters, such as battery capacity, the value of the battery health parameter should trend downwardly as time passes and/or as the battery is used. The process 300 can determine whether or not the battery health input values are trending in the correct direction by verifying that each battery health input value included in the plurality of battery health input values, for example, is less than the reference battery health value, which represents the current battery health value (e.g., the current battery capacity value). If one of the battery health input values is above the reference battery health value, there may be sensor errors involved in the calculation of the battery health input value, and the process 300 may prevent the reference battery health input value from being updated using potentially faulty data. Thus, in some embodiments, the process 300 can determine that each battery health input value meets the predetermined trend condition by determining that each battery health input value included in the plurality of battery health input values is less than the predetermined threshold. Otherwise, the process 300 can determine that each battery health input value does not meet the predetermined trend condition.

In some embodiments, the trend condition can require that each battery health input value included in the plurality of battery health input values is greater than a predetermined threshold. For certain battery health parameters, such as battery resistance, the value of the battery health parameter should trend upwardly as time passes and/or as the battery is used. Thus, in some embodiments, the process 300 can determine that each battery health input value meets the predetermined trend condition by determining that each battery health input value included in the plurality of battery health input values, for example, is greater than the predetermined threshold. Otherwise, the process 300 can determine that each battery health input value does not meet the predetermined trend condition.

At 324, if the process 300 has determined that each battery health input value does not meet the predetermined trend condition, (i.e., “NO” at 324), the process 300 can proceed to 304. At 324, if the process 300 has determined that each battery health input value meets the predetermined trend condition (i.e., “YES” at 324), the process 300 can proceed to 328.

At 328, the process 300 can calculate a difference value based on the updated battery health value and the reference battery health value. In some embodiments, the process 300 can calculate the difference value by subtracting the reference battery health value from the updated battery health value. Hence, the difference value for battery capacity should be a negative number indicating a decreasing battery capacity, while the difference value for battery resistance should be a positive number indicating an increasing battery resistance. While the below description calculates the difference values by subtracting the reference battery health value from the updated battery health value, those skilled in the art will understand that the difference value may likewise be determined by subtracting the updated battery health value from the reference battery health value or by determining absolute values, each accompanied with appropriate updating of value signs, applicable coefficients. and relative value comparisons without departing from the spirit of the concepts disclosed.

At 332, the process 300 can determine if the difference value is within an upper bound and a lower bound. To determine if the difference value is within the upper bound and the lower bound, in some examples, the process 300 can determine if the difference value is less than or equal to an upper bound battery health value and greater than or equal to a lower bound battery health value. In some examples, to determine if the difference value is within the upper bound and the lower bound the process 300 can determine if the difference value is less than the predetermined upper bound battery health value and greater than the predetermined lower bound battery health value. The process 300 may determine if the difference value is within the upper bound and the lower bound the process 300 by determining if the difference value is less than the predetermined upper bound battery health value and greater than or equal to the predetermined lower bound battery health value. Furthermore, the process 300 may determine if the difference value is within the upper bound and the lower bound the process 300 by determining if the difference value is less than or equal to the predetermined upper bound battery health value and greater than the predetermined lower bound battery health value.

In some embodiments, the process 300 can determine the upper bound battery health value and the lower bound battery health value based on the reference battery health value and a preceding battery reference health value. In some embodiments, the reference battery health value can be associated with a first time point, and the preceding battery reference health value can be associated with a second time point preceding the first time point. In this way, the process 300 can determine the upper bound battery health value and the lower bound battery health value using historical information of how the battery health value has been previously updated.

In some embodiments, the process 300 can determine the upper bound battery health value by calculating a bound difference value between the battery reference health value and the preceding battery reference health value. Specifically, the process 300 can calculate the bound difference value subtracting the preceding battery reference health value from the battery reference health value. For battery health parameters that trend downwardly (e.g., decreasing battery capacity), the bound difference value will be negative representing a decreasing difference value. The process 300 can determine the upper bound battery health value by multiplying the bound difference value by a first predetermined coefficient value. The first predetermined coefficient value may represent a percentage of the bound difference value (e.g., about 25% to 75%), such that the upper bound battery health value may be calculated by multiplying the bound difference value (e.g., a negative number in this instance) by the first coefficient value (e.g., about 0.25 to 0.75) and adding the product to the battery reference health value. Accordingly, the upper bound battery health value would be a value that is less than the battery reference health value. In some embodiments, the first coefficient value can be about 0.5 (e.g., about 50% of the bound difference). In some embodiments, the process 300 can determine the lower bound battery health value by multiplying the bound difference value by a second predetermined coefficient value. The second predetermined coefficient value may represent a percentage of the bound difference value (e.g., about 125% to 175%), such that the lower bound battery health value may be calculated by multiplying the bound difference (e.g., a negative number in this instance) by the second coefficient value (e.g., about 1.25 to 1.75) and adding the product to the battery reference health value. Accordingly, the lower bound battery health value would be a value that is less than the battery reference health value, and less than the upper bound battery health value. In some embodiments, the second coefficient value can be about 1.5 (e.g., about 150% of the bound difference).

In this way, the process 300 can determine whether the difference value is indicative an acceptable progression of the updated battery health value. If the difference value is too small or too large, the process 300 may not update the reference battery health value. For example, if the first coefficient value is 0.5 and the second coefficient value is 1.5, and the difference value is twice to the bound difference value (i.e., twice the magnitude of the last change to the reference battery health value), the process 300 will not update the battery health value as the difference value is too large. As another example, however, if the first coefficient value is 0.5 and the second coefficient value is 1.5, and the difference value is equal to the bound difference value (i.e., the magnitude of the last change to the reference battery health value), the process 300 will update the battery health value as the difference value is acceptable.

In some embodiments, the battery health parameter will trend upwardly (e.g., increasing battery resistance), and the bound difference value will be positive. In some embodiments having upwardly trending battery health parameters, the first coefficient value can be about 1.25 to 1.75. and the second coefficient value can be about 0.25 to 0.75. In some embodiments, the first coefficient value can be about 1.5, and the second coefficient value be about 0.5. It will be noted that in the above examples, the upper bound will remain the more numerically positive value, and the lower bound will remain the more numerically negative value and it is assumed the reference battery health value is treated as a positive value.

At 336, if the process 300 has determined that the difference value is not within the upper bound and the lower bound, (i.e., “NO” at 336), the process 300 can proceed to 304. At 324, if the process 300 has determined that the difference value is within the upper bound and the lower bound (i.e., “YES” at 336), the process 300 can proceed to 340.

At 340, the process 300 can update the reference battery health value to be equal to the updated battery health value.

At 344, the process 300 can generate a notification based on the updated reference battery health value. In some embodiments, the process 300 can determine that the updated reference battery health value is above and/or below a predetermined health indicator threshold. For example, the battery may have an end of service threshold and/or an elective replacement threshold. The predetermined health indicator threshold can include a predetermined value of the battery health parameter (e.g., battery capacity and/or battery resistance). The process 300 can compare the updated reference battery health value to the predetermined value of the battery health parameter. For some battery health parameters, such as battery capacity, the process 300 can determine if the updated reference battery health value is equal to and/or less than the predetermined value of the battery health parameter. For some battery health parameters, such as battery resistance, the process 300 can determine if the updated reference battery health value is equal to and/or greater than the predetermined value of the battery health parameter. If the updated reference battery health value meets the predetermined health indicator threshold, the process 300 can generate a warning notification that the battery is at an end of service threshold and/or an elective replacement threshold. In some embodiments, the process 300 can generate the notification to indicate that the reference battery health value has been updated.

At 348, the process 300 can cause any generated notifications to be displayed at a user interface. In some embodiments, the process 300 can cause the notification to be displayed at the output device 232 and/or the actuators 256 in FIG. 2. In some embodiments, the process 300 can proceed to 304. In some embodiments, the process 300 can end.

FIG. 3B illustrates an exemplary flow diagram of another process 352 for updating a battery health value using a multistage filtering technique. Referring to FIG. 3B as well as FIG. 1, FIG. 2, and FIG. 3A, in some embodiments, the process 352 can be implemented as instructions in the processor 204, the memory 208, the storage 212, and/or the battery controller 260 in (e.g., as instructions 240). In some embodiments, the process 352 can be executed by the controller 104 in (e.g., by the processor 204), and another portion of the process 352 can be executed by the battery controller 260. In some embodiments, the process 352 may be executed by only the controller 104. In other embodiments, the process 352 may be executed by only the battery controller 260. The process 352 can be used to monitor the health of the battery 108. In some embodiments, the process 352 can include at least a portion of the process 300 in FIG. 3A.

Referring now to FIG. 3B, at 356, the process 352 can receive a plurality of battery health input values associated with a battery health parameter. In some embodiments, at 356, the process 352 can execute at least a portion of the process 300 at 304, 308, and/or 312 in FIG. 3A.

At 360, the process 352 can determine an updated battery health value based on the plurality of battery health input values. In some embodiments, at 360, the process 352 can execute at least a portion of the process 300 at 316 in FIG. 3A.

At 364, the process 352 can determine if each battery health input value meets a predetermined trend condition. In some embodiments, at 364, the process 352 can execute at least a portion of the process 300 at 320, 324, 308, and/or 312 in FIG. 3A. If the process 352 determines that at least one battery health input value does not meet the predetermined trend condition (i.e., “NO” at 364), the process 352 can proceed to 356. If the process 352 determines that each battery health input value meets the predetermined trend condition (i.e., “YES” at 364), the process 352 can proceed to 368.

At 368, the process 352 can calculate a difference value based on the updated battery health value and a reference battery health value. In some embodiments, at 368, the process 352 can execute at least a portion of the process 300 at 328 in FIG. 3A.

At 372, the process 352 can determine if the difference value is within an upper bound and a lower bound. In some embodiments, the process 352 can determine if the difference value is less than or equal to an upper bound battery health value and greater than or equal to a lower bound battery health value. In some embodiments, at 372, the process 352 can execute at least a portion of the process 300 at 332 and/or 336 in FIG. 3A. If the process 352 determines that the difference value is not the upper bound and the lower bound (i.e., “NO” at 372), the process 352 can proceed to 356. If the process 352 determines that the difference value is within the upper bound and the lower bound (i.e., “YES” at 372), the process 352 can proceed to 376.

At 376, the process 352 can update the reference battery health value to be equal to the updated battery health value. In some embodiments, at 376, the process 352 can execute at least a portion of the process 300 at 340, 344, and/or 348 in FIG. 3A.

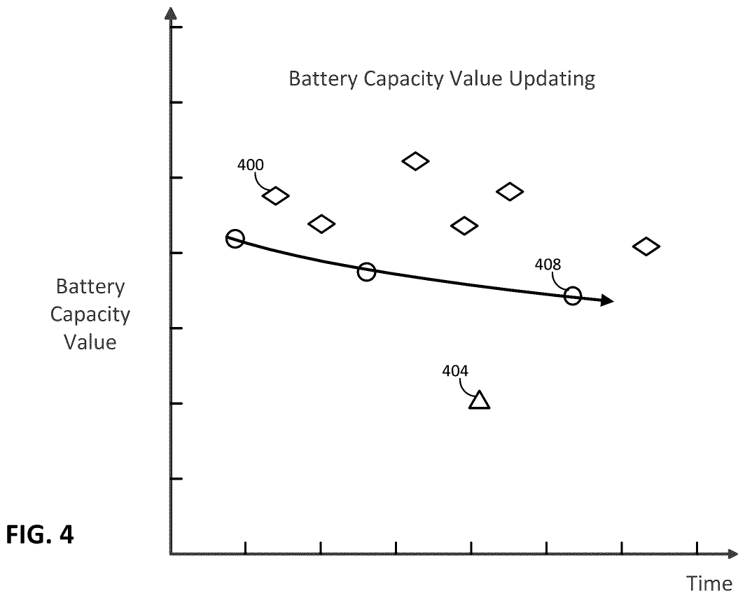

FIG. 4 illustrates an exemplary battery capacity value updating graph. As time goes on, the battery capacity of an exemplary battery may decrease. However, certain sensor readings may be faulty. The process 300 in FIG. 3A can filter out values based on sensor data (i.e., either raw or calculated values) that may be faulty. In particular, certain values indicated by rhombi 400 may be higher than the current reference battery health value, and may not be used to update the reference battery health value. Additionally, certain values indicated by a triangle 404 may be significantly lower than the current reference battery health value, and may not be used to update the reference battery health value. Certain values indicated by circles 408 may meet all the filtering criteria of the process 300 (e.g., at 308, 324, and 336) and be used to update the reference battery health value.

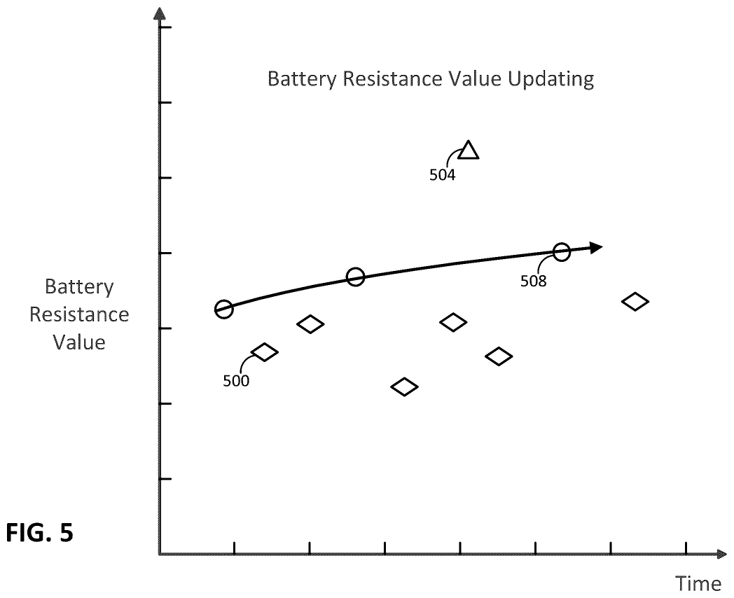

FIG. 5 illustrates an exemplary battery resistance value updating graph. As time goes on, the battery resistance of an exemplary battery may increase. However, certain sensor readings may be faulty. The process 300 in FIG. 3A can filter out values based on sensor data (i.e., either raw or calculated values) that may be faulty. In particular, certain values indicated by rhombi 500 may be lower than the current reference battery health value, and may not be used to update the reference battery health value. Additionally, certain values indicated by a triangle 504 may be significantly higher than the current reference battery health value, and may not be used to update the reference battery health value. Certain values indicated by circles 508 may meet all the filtering criteria of the process 300 (e.g., at 308, 324, and 336) and be used to update the reference battery health value.

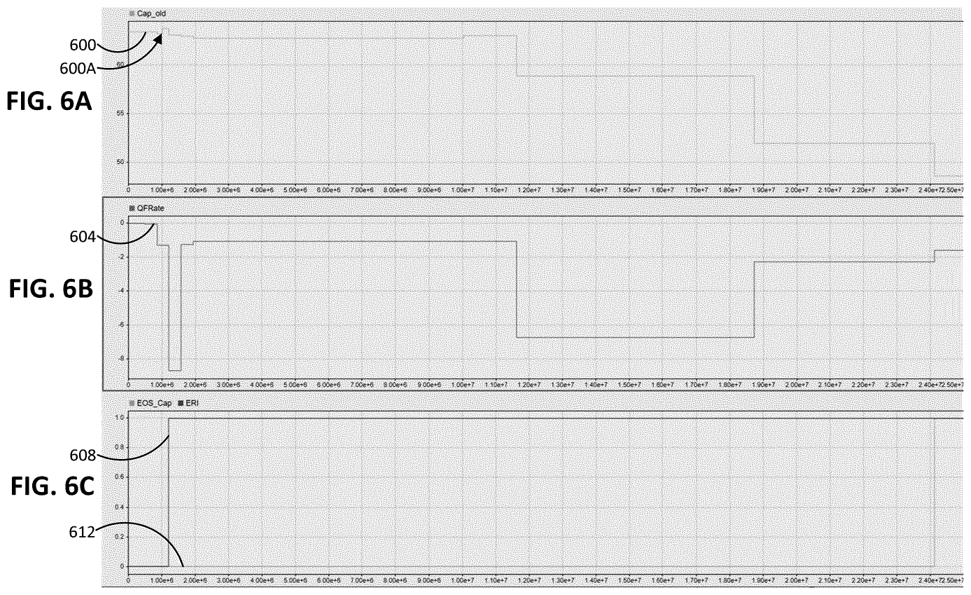

FIG. 6A illustrates a battery capacity value trend line graph without using a multistage filtering technique (e.g., the process 300 in FIG. 3A). The graph includes a battery capacity value trend line 600 having an aberration 600A. Without the multistage filtering technique, the aberration 600A will cause other parameters to be miscalculated.

FIG. 6B illustrates a battery capacity fade rate value trend line graph without using a multistage filtering technique. The graph includes a battery capacity fade rate value trend line 604. Without the multistage filtering technique, the aberration 600A in FIG. 6A was not filtered out, and the battery capacity fade rate value was miscalculated based on the aberration 600A.

FIG. 6C illustrates an elective replacement indicator value and end of service indicator value trend line graph without using a multistage filtering technique. An elective replacement indicator value trend line 608 is set too early based on the aberration 600A in FIG. 6A. The graph also includes an end of service indicator value trend line 612.

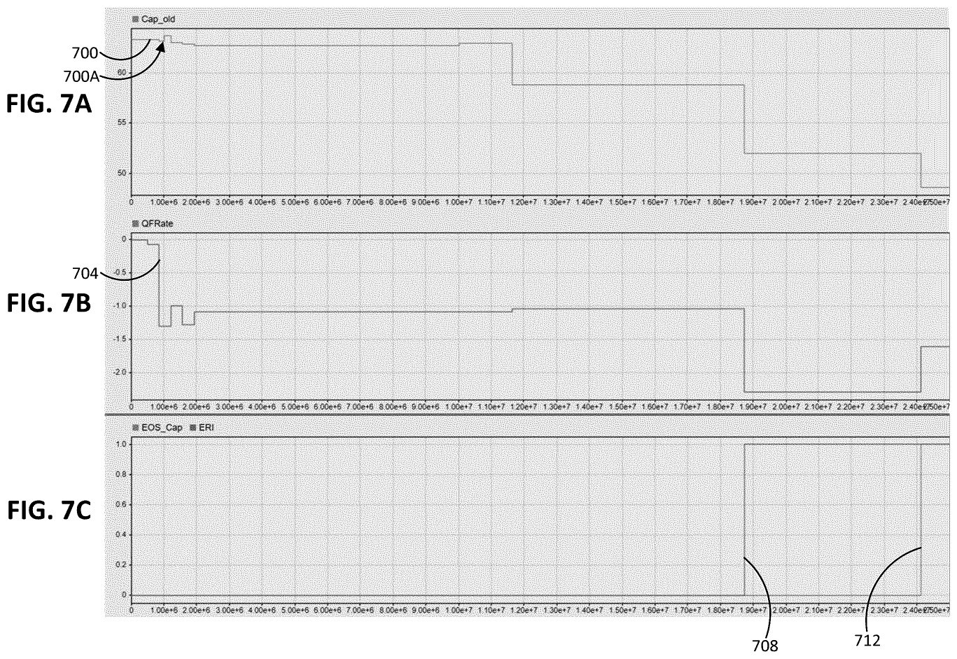

FIG. 7A illustrates a battery capacity value trend line graph using a multistage filtering technique. Technique (e.g., the process 300 in FIG. 3A). The graph includes a battery capacity value trend line 700 having an aberration 700A. With the multistage filtering technique, the aberration 700A will not cause other parameters to be miscalculated.

FIG. 7B illustrates a battery capacity fade rate value trend line graph using a multistage filtering technique. The graph includes a battery capacity fade rate value trend line 704. With the multistage filtering technique, the aberration 700A in FIG. 7A is filtered out, and the battery capacity fade rate value is properly calculated.

FIG. 7C illustrates an elective replacement indicator value and end of service indicator value trend line graph using a multistage filtering technique. An elective replacement indicator value trend line 708 is set properly because the multistage filtering process removes the aberration 700A in FIG. 7A from consideration in updating the reference battery capacity value. The graph also includes an end of service indicator value trend line 712.

FIG. 8 illustrates an exemplary imaging system 800 in accordance with some embodiments. In some embodiments, the imaging system 800 can be a portable imaging system (e.g., a portable x-ray imaging system). In some embodiments, the imaging system 800 can be an O-ARM™ imaging system from Medtronic. In some embodiments, the imaging system 800 can include imaging subsystem 804 and a control subsystem 808. In some embodiments, the imaging subsystem 804 can be included in the medical subsystem 112 in FIG. 1. In some embodiments, at least a portion of the control subsystem 808 can be included in the controller 104 in FIG. 1. In some embodiments, the control subsystem can include a battery (not shown). In some embodiments, the control subsystem 808 can provide power to the imaging subsystem 804 using the battery.

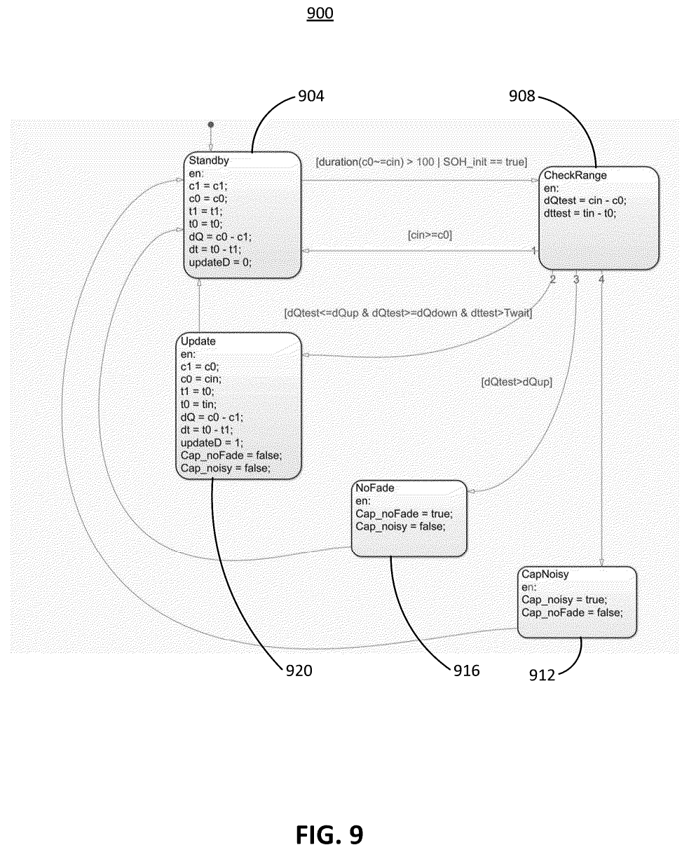

FIG. 9 illustrates an exemplary process 900 for filtering battery capacity values. At 900, the process 900 can receive a number of sequential battery capacity values. If the battery capacity values are not equal to a stored battery capacity value for at least one hundred seconds, or if an initialization state (i.e., SOH_init in FIG. 9) is true, the process 900 can proceed to 908. At 908, the process 900 can determine if an input battery capacity value is greater than the stored battery capacity value, and if so, proceed to 904. Otherwise the process 900 can proceed to 912, 916, and 920. At 912, the process 900 can determine if the capacity is noisy and set a noisy flag. At 916, the process 900 can set a no fade flag. At 920, the process 900 can update one or more reference battery capacity values because the input battery capacity value passed all filtering conditions. The process 900 can also reset the noisy flag and the no fade flag.

As used herein, the terms “machine-readable medium” and “computer-readable medium” are interchangeable. In further examples, a machine-readable medium also includes any tangible medium that is capable of storing, encoding or carrying instructions for execution by a machine and that cause the machine to perform any one or more of the methodologies of the present disclosure or that is capable of storing, encoding or carrying data structures utilized by or associated with such instructions. A “machine-readable medium” thus may include but is not limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks. The instructions embodied by a machine-readable medium may further be transmitted or received over a communications network using a transmission medium via a network interface device utilizing any one of a number of transfer protocols (e.g., Hypertext Transfer Protocol (HTTP)).

A machine-readable medium may be provided by a storage device or other apparatus which is capable of hosting data in a non-transitory format. In an example, information stored or otherwise provided on a machine-readable medium may be representative of instructions, such as instructions themselves or a format from which the instructions may be derived. This format from which the instructions may be derived may include source code, encoded instructions (e.g., in compressed or encrypted form), packaged instructions (e.g., split into multiple packages), or the like. The information representative of the instructions in the machine-readable medium may be processed by processing circuitry into the instructions to implement any of the operations discussed herein. For example, deriving the instructions from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions.

Various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules associated with, for example, a medical device.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that can be used to store desired program code in the form of instructions or data structures and that can be accessed by a computer).

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor” as used herein may refer to any of the foregoing structure or any other physical structure suitable for implementation of the described techniques. Also, the techniques could be fully implemented in one or more circuits or logic elements.

What is claimed is:

1. A battery health management device comprising:
at least one sensor coupled to a battery; and
a controller coupled to the at least one sensor and comprising a processor coupled to a memory comprising instructions, the processor configured to execute the instructions to:
receive, using the at least one sensor, a plurality of battery health input values associated with a battery health parameter over a predetermined period of time;
determine an updated battery health value based on the plurality of battery health input values;
determine that each battery health input value included in the plurality of battery health input values meets a predetermined trend condition;
calculate a difference value based on the updated battery health value and a reference battery health value associated with the battery;
determine that the difference value is less than or equal to a predetermined upper bound battery health value and greater than or equal to a predetermined lower bound battery health value; and
update the reference battery health value to be equal to the updated battery health value.

2. The battery health management device of claim 1, wherein the processor is further configured execute the instructions to:
generate a notification based on the updated reference battery health value; and
cause the notification to be displayed at a user interface.

3. The battery health management device of claim 1, wherein the determining that each battery health input value included in the plurality of battery health input values meets the predetermined trend condition comprises:
determining that each battery health input value included in the plurality of battery health input values is less than the reference battery health value.

4. The battery health management device of claim 1, wherein the determining that each battery health input value included in the plurality of battery health input values meets the predetermined trend condition comprises:
determining that each battery health input value included in the plurality of battery health input values is greater than the reference battery health value.

5. The battery health management device of claim 1, wherein the battery health parameter is one of battery resistance or battery capacity.

6. The battery health management device of claim 1, wherein the determining the updated battery health value based on the plurality of battery health input values comprises:
calculating a mean, median, or modal battery health input value based on the plurality of battery health input values; and
setting the updated battery health value to be equal to the mean, median, or modal battery health input value.

7. The battery health management device of claim 1, wherein the reference battery health value is associated with a first time value, and the predetermined upper bound battery health value is determined based on the reference battery health value and a second reference battery health value associated with a second time value preceding the first time value.

8. The battery health management device of claim 1, wherein the processor is further configured execute the instructions to:
calculate the predetermined upper bound battery health value based on the difference between the second reference battery health value and the reference battery health value.

9. The battery health management device of claim 1, wherein the reference battery health value is associated with a first time value, and the predetermined lower bound battery health value is determined based on the reference battery health value and a second reference battery health value associated with a second time value preceding the first time value.

10. The battery health management device of claim 9, wherein the processor is further configured execute the instructions to:
calculate the predetermined lower bound battery health value based on the difference between the reference battery health value and the second reference battery health value.

11. The battery health management device of claim 1, wherein the processor is further configured to execute the instructions to:
determine each battery health input value is not equal to the reference battery value.

12. The battery health management device of claim 1, wherein the battery health management device includes the battery, and wherein the battery comprises a lithium ion battery included in a medical imaging device.

13. A health management method for a battery comprising:
receiving, using at least one sensor coupled to the battery, a plurality of battery health input values associated with a battery health parameter over a predetermined period of time;
determining an updated battery health value based on the plurality of battery health input values;
determining that each battery health input value included in the plurality of battery health input values meets a predetermined trend condition;
calculating a difference value based on the updated battery health value and a reference battery health value associated with the battery;
determining that the difference value is less than or equal to a predetermined upper bound battery health value and greater than or equal to a predetermined lower bound battery health value; and
updating the reference battery health value to be equal to the updated battery health value.

14. The method of claim 13, wherein the determining the updated battery health value based on the plurality of battery health input values comprises:
calculating a mean, median, or modal battery health input value based on the plurality of battery health input values; and
setting the updated battery health value to be equal to the mean, median, or modal battery health input value.

15. The method of claim 13 further comprising:
generating a notification based on the updated reference battery health value; and
causing the notification to be displayed at a user interface.

16. The method of claim 13, wherein the determining that each battery health input value included in the plurality of battery health input values meets the predetermined trend condition comprises;
determining that each battery health input value included in the plurality of battery health input values is less than the reference battery health value.

17. The method of claim 13, wherein the determining that each battery health input value included in the plurality of battery health input values meets the predetermined trend condition comprises:
determining that each battery health input value included in the plurality of battery health input values is greater than the reference battery health value.

18. The method of claim 13, wherein the reference battery health value is associated with a first time value, and the predetermined upper bound battery health value is determined based on the reference battery health value and a second reference battery health value associated with a second time value preceding the first time value, the method further comprising calculating the predetermined upper bound battery health value based on the difference between the second reference battery health value and the reference battery health value.

19. The method of claim 18 further comprising:
calculating the predetermined lower bound battery health value based on the difference between the reference battery health value and the second reference battery health value.

20. A non-transitory computer readable medium storing computer program instructions for health management of a battery, the computer program instructions when executed by a processor cause the processor to perform operations comprising;
receiving, using at least one sensor coupled to the battery, a plurality of battery health input values associated with a battery health parameter over a predetermined period of time;
determining an updated battery health value based on the plurality of battery health input values;
determining that each battery health input value included in the plurality of battery health input values meets a predetermined trend condition;
calculating a difference value based on the updated battery health value and a reference battery health value associated with the battery;
determining that the difference value is less than or equal to a predetermined upper bound battery health value and greater than or equal to a predetermined lower bound battery health value; and
updating the reference battery health value to be equal to the updated battery health value.
